(19) United States
(12) Patent Application Publication
(10) Pub. No.: US 2004/0264713 A1
(43) Pub. Date: Dec. 30, 2004

(54) Adaptive audio communication code

(76) Inventor: Robert Grzesek, Redondo Beach, CA (US)

Correspondence Address: ROY A. EKSTRAND, MATTEL, INC., 333 CONTINENTAL BLVD., EL SEGUNDO, CA, 90245, US

(21) Appl. No.: 10/609,043

(22) Filed: Jun. 27, 2003

(51) Int. Cl. H03G 5/00

(52) U.S. Cl. 381/101

(57) ABSTRACT

Data is encoded as a number of audio tones forming a leader tone, a series of tones forming a start symbol and a greater number of data symbols following the start symbol which are each formed of a group of audio tones. The information is transmitted from a speaker or similar transducer to a microphone or similar transducer. The microphone is coupled to the input of a personal computer within which software is operative to analyze and decode the information. The leader tone is used to determine any frequency inaccuracies or errors which have occurred in the system. Based upon detected frequency inaccuracy or deviation, a frequency offset is employed within the system upon all received audio tones to adapt the system to the frequency inaccuracies or errors and produce correct data.

### FIELD OF THE INVENTION

This invention relates generally to audio communication systems and particularly to apparatus and methods for improving the reliability and noise tolerance of such systems.

### BACKGROUND OF THE INVENTION

Communication of data utilizing audio signals or tones is well known and well established within the art. Such communication systems operate utilizing various communication media. For example, in many systems actual direct or wire connection is employed. In others, audio code information is modulated upon a radio frequency carrier and communicated between a transmitter and one or more receivers. Finally many systems utilize communication of audio code data in direct sound communication and reception.

The basic system utilized in audio code communication is relatively simple to understand and implement. For the most part, such systems rely upon encoding data in the form of a plurality of tones or audio bursts arranged and organized in accordance with a predetermined data code format. In essence, this provides for the representation and communication of complex information and data in the form of one or more series of audio code signal tones or bursts. In direct through the air communication systems, the transfer of information is relatively simple in that a sending unit employs an electro-audio transducer such as a speaker or piezoelectric type device to convert electrical data signals to appropriately coded audio tones. At the receiving unit, an acoustic transducer reverses the process utilizing a conventional microphone or a second piezoelectric device to convert the audio tones to corresponding electronic signals. In most systems, the coded information is digital in character which is particularly advantageous in utilizing audio code communication.

Audio code communication systems enjoy several significant advantages which include relatively low cost and simple components and technologies for the basic system. In addition, the communication via through-the-air audio code formats is extremely safe in that the communicated energy is simply sound energy. As a result, no regulation or licensing by governing bodies is typically required and no harmful energy is produced. In addition, a further advantage in audio code communication systems lies in the relatively low amount of power required for effective communication rendering the system ideal for battery powered units further advantage which arises in an interesting aspect, is found in the entertainment and amusement which users seem to find in the sounds made by audio code communication apparatus.

Unfortunately, the many advantages of audio code communication systems are balanced by several limitations. Perhaps one of the most serious limitations is the vulnerability of audio code communication systems to interference from extraneous audio sources such as ambient noise or the like. Because many audio code communication systems operate using sound frequencies which coincide with the frequencies with other sound sources, the system communication is often compromised or corrupted by noise and false data. In addition, significant noise impede or completely undermine the operation of the communication system. In essence, the overlapping frequencies of sound used in an audio code communication system and extraneous or ambient sound sources may prove difficult or impossible for the audio code communication system to ignore or distinguish.

Another problem frequently encountered in audio code communication system lies in the difficulties associated with producing and maintaining accurate frequency information. Since most audio code communication systems rely, at least in part, upon frequency information for coding and noise tolerance, accurate frequency creation and detection is fundamental to system operation. However, such accurate generation and communication and reception of audio information is often difficult in a practical cost effective environment.

Motivated by the many advantages to be obtained in utilizing audio code communication systems, practitioners in the art have endeavored to overcome the disadvantages and limitations imposed by problems such as ambient noise or extraneous sound source interference. For example, U.S. Pat. No. 5,539,705 issued to Akerman et al. sets forth an ULTRASONIC SPEECH TRANSLATOR AND COMMUNICATION SYSTEM having an ultrasonic transmitting device and an ultrasonic receiving device. The ultrasonic transmitting device excepts as input an audio signal such as the human voice input from a microphone or tape deck. The ultrasonic transmitting device frequency modulates an ultrasonic carrier signal with the audio signal producing a frequency modulated ultrasonic signal which is transmitted via acoustical pressure waves through a carrier medium. The ultrasonic receiving device converts the frequency modulated ultrasonic acoustical pressure waves to a frequency modulated electronic signal which is demodulated to recover the audio information.

U.S. Pat. No. 5,495,357 issued to Osterhout sets forth an APPARATUS AND METHOD FOR RECORDING, TRANSMITTING, RECEIVING AND PLAYING SOUNDS which includes a record switch for recording messages to be sent, a transmit switch for sending messages, a play switch for playing recorded and received messages, a microphone for converting sound waves into electrical signals indicative of sound waves, an audio recorder for recording and playing back electrical signals, a transmitter for transmitting electromagnetic signals, a receiver for receiving electromagnetic signals and ,a speaker for converting electrical signals into sound waves. All devices are enclosed within a single compact housing. The device is small enough to be worn on the clothing of a person.

U.S. Pat. No. 5,625,843 issued to Lee sets forth an AUDIO DATA INPUT DEVICE FOR MULTI-MEDIA COMPUTER which converts an audio signal output from a microphone into digital audio data and inputs the audio data together with an audio clock to a computer system. The system employs a keyboard or mouse connector to simplify the computer system structure and obtain enhanced user convenience.

U.S. Pat. No. 5,832,438 issued to Bauer sets forth an APPARATUS AND METHOD FOR AUDIO COMPUTING for handling audio signals which includes programmable digital processing circuitry, read write memory, digital to analog circuitry one or more speakers, and an equalization element for altering the frequency response of signals applied to the speaker. The equalization element can be used to boost low frequency signals sent to the speaker in order to compensate for poor, low frequency response of the speaker.

U.S. Pat. No. 5,675,708 issued to Fitzpatrick et al. sets forth an AUDIO MEDIA BOUNDARY TRAVERSAL METHOD AND APPARATUS which transforms a multimedia data stream or file into an audio stream that is understandable to humans. The system then transforms the audio output back to the original multimedia stream or file without lose of information.

U.S. Pat. No. 5,297,231 issued to Miller sets forth a DIGITAL SIGNAL PROCESSOR INTERFACE FOR COMPUTER SYSTEM having compressed parallel digital audio data originating one a system bus associated with the computer. The data is transmitted to a first data interface in which the compressed parallel digital audio data is converted into compressed serial digital audio data. The compressed serial digital audio data is then transmitted to a second data interface associated with a digital signal processor. The second data interface routes the compressed serial digital audio data from the first data interface to the digital signal processor in which the data is expanded and then returned to the second data interface.

U.S. Pat. No. 5,878,187 issued to Kubota et al. sets forth a DIGITAL SIGNAL RECORDING METHOD AND RECORDING APPARATUS THEREOF in which input digital data is recorded on inclined tracks of a magnetic tape. The general and continuous data are recorded as SYNC blocks on different tracks. A number of general data SYNC blocks of one track are divided into sub units. The general data sub units are arranged in the same format as the continuous audio data for recording.

U.S. Pat. No. 5,971,855 issued to Ng sets forth an APPARATUS AND METHOD OF COMMUNICATING BETWEEN ELECTRONIC GAMES in which a personal computer is operatively coupled to an internet website. The personal computer is further coupled via a tether to a game unit such that information may be exchanged between the game unit and the website through the personal computer.

U.S. Pat. No. 5,870,710 issued to Ozawa et al. sets forth an AUDIO TRANSMISSION, RECORDING AND REPRODUCING SYSTEM having a controller for controlling the entire operation, a hard disk for write and read audio data, audio compression/expansion circuitry and an external I/O port. The audio recording and reproducing apparatus is connected to a network service to obtain desired music data from storage within the network service and to store it in the hard disk in the system.

U.S. Pat. No. 6,185,527B1 Issued to Petkovic et al. sets forth a SYSTEM AND METHOD FOR AUTOMATIC AUDIO CONTENT ANALYSIS FOR WORD SPOTTING, INDEXING, CLASSIFICATION AND RETRIEVAL having specialized audio pre-filtering such that only relevant speech segments that are generated by a speech recognition engine or indexed. Specific indexing features are utilized that improve the precision and recall of information retrieval within the system used for word spotting. The system includes rendering the audio stream into intervals with each interval including one or more segments. Within each segment of an interval, a determination is made as to whether the segment exhibits one or more predetermined audio features.

U.S. Pat. No. 5,764,763 issued to Jensen et al. sets forth an APPARATUS AND METHODS FOR INCLUDING TONES IN AUDIO SIGNALS AND DECODING having at least one code frequency component in an audio signal. The abilities of various frequency components in the audio signal to mask the code frequency component to human hearing are evaluated and based upon these evaluations an amplitude is assigned to the code frequency, component.

U.S. Pat. No. 3,793,636 issued to Clark et al. sets forth a NONCONDUCTIVE DATA LINK CONTROL APPARATUS operative between command and response locations remote from each other. The data link control apparatus accomplishes substantially proportional control and includes safety features to prevent outside interference.

U.S. Pat. No. 4,110,725 issued to Petrosky sets forth a SEQUENTIAL TONE ACOUSTIC COMMAND LINK in which an acoustic multi-tone code signal is transmitted through a water environment to a receiver unit. The receiver unit includes a multi-tone decoder. In the event the signal to noise ratio of the input signal is above a predetermined threshold, the coded signal is passed to the decoder which provides an output control signal in accordance with the particular code.

U.S. Pat. No. 4,806,931 issued to Nelson sets forth a SOUND PATTERN DISCRIMINATION SYSTEM while U.S. Pat. No. 3,744,030 issued to Kuijian sets forth an INTRINSIC CONTROL FOR INFORMATION RETRIEVAL SYSTEMS EMPLOYING. DIGITAL CODES INTEGRAL WITH AUDIO INFORMATION both of which utilized combined systems for communicating audio information.

U.S. Pat. No. 5,735,285 issued to Albert et al. sets forth a METHOD AND HAND-HELD APPARATUS FOR DEMODULATING AND VIEWING FREQUENCY MODULATED BIOMEDICAL SIGNALS in which data from a patient is transmitted to an attending physician via the telephone system.

U.S. Pat. No. 5,048,831 issued to Sides sets forth an ELECTRONIC GAME APPARATUS AND METHOD OF USE for use by a single player which is also usable for direct competitive play between two or more players. The communication between competing game apparatus is both direct physical communication through a physical linkage as well as radio signals or the like.

U.S. Pat. No. 5,209,695 issued to Rothschild sets forth a SOUND CONTROLLABLE APPARATUS PARTICULARLY USEFUL IN CONTROLLING TOYS AND ROBOTS while U.S. Pat. No. 4,717,364 issued to Furukawa sets forth a VOICE CONTROL TOY both of which illustrate toy apparatus operated under the control of audio information.

U.S. Pat. No. 5,618,045 issued to Kagan et al. and U.S. Pat. No. 5,364,108 issued to Esnouf set forth examples of game and toy apparatus using sound as part of the game play.

While the foregoing described prior art devices have to some extent improved the art and have in some instances enjoyed commercial success, there remains nonetheless a need in art for an audio communication code system which meets the difficulties associated with ambient noise and extraneous noise source interference.

### SUMMARY OF THE INVENTION

Accordingly, it is a general object of the present invention to provide an improved audio communication code system and method. It is a more particular object of the present invention to provide an improved audio communication code system and method which overcomes problems generally associated with ambient noise interference and system failure due to extraneous noise sources.

In accordance with the present invention there is provided an audio communication code comprising: a leader tone having a sound tone at a selected frequency, the leader tone having a first time interval; a start symbol following the leader tone having a predetermined sequence of sound tones, the start symbol being indicative of a plurality of data symbols to follow; a plurality of data symbols following the start symbol having a plurality of sound tone sets the frequencies of the sound tones in each sound tone set defining data corresponding to the data in its respective sound tone set, the leader tone frequency being used to determine a frequency offset of the leader tone from the selected frequency which is ten applied to the start symbol and the data symbols as a frequency correction.

From an alternate perspective, the present invention also provides an audio communication code method comprising the steps of: forming a leader tone having a sound tone at a selected frequency, the leader tone having a first time interval; forming a start symbol following the leader tone having a predetermined sequence of sound tones, the start symbol being indicative of a plurality of data symbols to follow; forming a plurality of data symbols following the start symbol having a plurality of sound tone sets the frequencies of the sound tones in each sound tone set defining data corresponding to the data in its respective sound tone set, the leader, tone frequency being used to determine a frequency offset of the leader tone from the selected frequency which is ten applied to the start symbol and the data symbols as a frequency correction; converting the leader tone, the start symbol and the plurality of data symbols to sound energy; receiving the sound energy at a receiver and converting it to electrical signal; detecting the frequency of the leader tone as received and Converted; determining the frequency offset of the detected frequency from the selected frequency; offsetting the tones of the start symbol and the plurality of data symbols by the frequency offset; and decoding the data symbols having the frequency offset to recover the data.

### BRIEF DESCRIPTION OF THE DRAWINGS

The features of the present invention, which are believed to be novel, are set forth with particularity in the appended claims. The invention, together with further objects and advantages thereof, may best be understood by reference to the following description taken in conjunction with the accompanying drawings, in the several figures of which like reference numerals identify like elements and in which:

FIG. 1 sets forth a perspective view of an audio communication system utilizing the present invention adaptive audio communication code;

FIG. 2 sets forth a audio communication code wave form constructed in accordance with the present invention;

FIG. 3 sets forth a block diagram of the adaptive portion of the present invention audio communication code;

FIG. 4 sets forth a flow diagram of the operation of the present invention adaptive audio: communication code;

FIG. 5 sets forth the remainder of the flow diagram of the present invention adaptive audio communication code of FIG. 4.

### DESCRIPTION OF THE PREFERRED EMBODIMENT

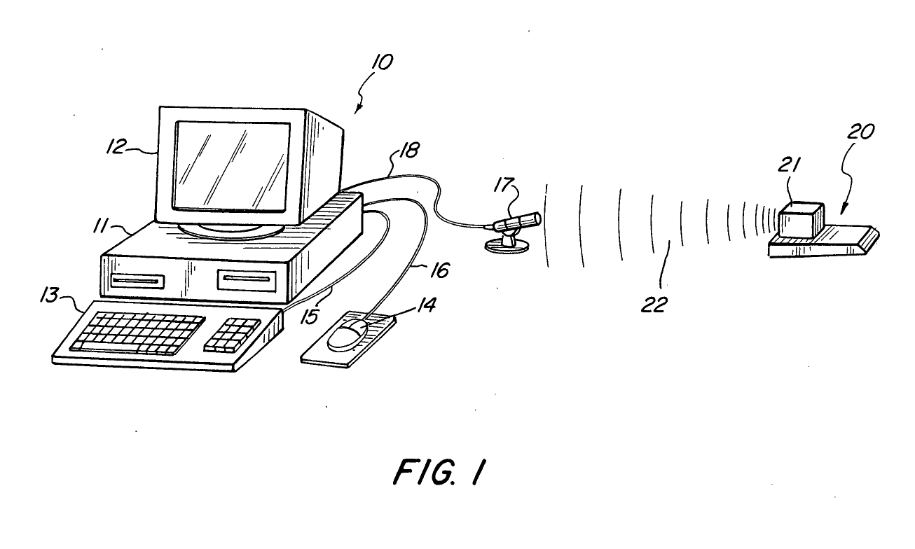

FIG. 1 sets forth a perspective view of a computing system constructed in accordance with conventional fabrication techniques and generally referenced by numeral 10. Thus, in accordance with conventional techniques, personal computer 10 includes a processor unit 11 having appropriate means for receiving various input material such as magnetic disk and/or compact disks. Personal computer 10 further includes a monitor 12 for displaying images thereon together with a conventional keyboard 13. Keyboard 13 is coupled to processor unit 11 by a connecting cable 15. In addition, personal computer 10 includes a conventional mouse coupled to processor unit 11 by a cable 16. Finally, personal computer 10 includes a micro phone 17 coupled to processor unit 11 by a connecting cable 18.

It will be noted that while personal computer 10 is described as being constructed in accordance with conventional fabrication techniques, the present invention adaptive audio communication code software is resident within personal computer 10 to provide the novel operation described below. In fulfilling the objective of providing adaptive audio communication code, microphone 17 is configured to receive audible sound and to produce electrical signals in accordance therewith which are coupled by cable 18 to processor unit 11.

In further accordance with the present invention, an audio transmitting unit 20 includes internal apparatus for producing encoded audio data which is applied to a speaker 21 also resident with audio transmission unit 20. Speaker 21 responds to the applied audio communication code data to produce sound 22. Sound 22 propagates outwardly from speaker 21 and is sensed by microphone 17 which then converts the audio data to corresponding electrical signals which as mentioned above, are applied to processor unit 11 by connecting cable 18.

In accordance with the present invention, it will be noted that in an arrangement such as that set forth in FIG. 1, in which the audio communication code information is transferred by sound energy between a speaker and a microphone, a number of the above described problems arise. For example, the frequency responses of both speaker 21 and microphone 17 are often less than ideal. This means that the audio data produced by speaker 21 may differ somewhat from the actual signal frequency intended with the code format. Similarly, the frequency response of microphone 17 may also be less than ideal in which case, the detected sound waves may be reproduced inaccurately resulting in electrical signals which differ in frequency from the intended frequencies. In addition to possible errors arising due to the less than ideal frequency characteristics of both speaker 21 and microphone 17, the possible interference of ambient noise within the environment also arises. It will be apparent to those skilled in the art that while sound energy waves 22 propagate from speaker 21 to microphone 17, microphone 17 in no way excludes other noises arising due to ambient noise sources in the area. On the contrary, the sound energy created by ambient noise sources within the area about microphone 17 are detected and converted to corresponding electrical signals which are passed on to processor unit 1. Thus, an effective audio communication code system must overcome and/or compensate for problems arising due to ambient noise as well as frequency inaccuracies of the equipment being utilized.

In accordance with the present invention and as is described below in greater detail, the audio communication code utilized in the present invention provides sound energy 22 which is configured or formatted to aide the system running on personal computer 10 in successfully retrieving the transmitting data notwithstanding ambient noise and frequency inaccuracies of the system hardware.

While the present invention adaptive audio communication code is described below in greater detail, suffice it to note here that the present invention adaptive audio communication code utilizes a leader tone which precedes a start symbol which in turn precedes a plurality of multi-tone data symbols. The leader portion functions to provide a beacon-which indicates to the receiver that an audio signal is forthcoming. In addition, the leader portion of the present invention adaptive audio communication code utilizes the frequency of the recovered leader tone to determine inaccuracies in frequency and timing of the signal which have occurred during the transmission reception and conversion from sound energy to electrical energy. Finally, the present invention adaptive audio communication code system utilizes this detection of frequency and timing inaccuracies to implement a frequency offset utilized in all symbol tone detection which overcomes the problems which would otherwise be associated with such errors in frequency or timing. In this manner, the present invention system is adaptive in that it adjusts in real time to meet inaccuracies and frequency shifts which have occurred during transmission and reception.

In addition, and as is also described in greater detail, the start symbol which follows the leader tone and which precedes the data symbols is unique to the system and provides important timing information which may be utilized to properly decode the data symbols. Finally, each data symbol is comprised of a plurality of tones. The primary advantage of such multiple tone symbol use is found in greatly improved noise rejection. Because to signal is designed to be received via a microphone, such as seen in FIG. 1, it becomes extremely important to overcome problems produced by ambient noise in the immediate area of PC 10 and audio transmitting unit 20. In addition, the formation of data symbols as a collection of tones facilitates the representation of multiple bits of data thereby providing a higher data rate than can be achieved by a corresponding binary data system. Finally, in order to reduce the probability of errors within the present invention adaptive audio communication code, the selection of symbols used within the code is chosen to reduce the probability of an error.

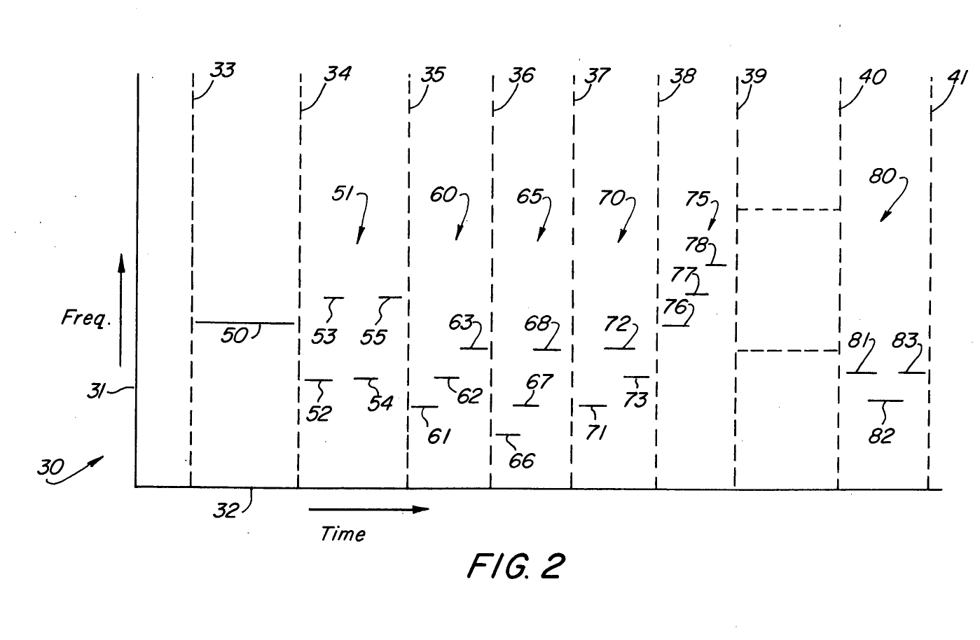

FIG. 2 sets forth an example of the present invention adaptive audio communication code generally referenced by numeral 30. Audio communication code signal 30 is shown in FIG. 2 as a frequency verses time wave form. Thus, vertical axis 31 is indicative of increasing frequency while horizontal axis 32 is indicative of ongoing time.

More specifically, signal 30 which is initiated at time 33 includes a single frequency leader tone 50 extending to time 34. In the preferred fabrication of the present invention adaptive audio communication code, the selection for the time duration of leader 50 is preferably chosen to equal or exceed the intervals for remaining data and leader symbols described below. Suffice it to note here that while the time interval of leader tone 50 may be varied in accordance with the particular needs of the host audio communication codes system, the important aspect with respect to the present invention is sufficient length of interval to allow the system to detect, measure and respond to both the presence of the leader tone and the actual frequency of the leader tone. Thus, leader tone 50 is a constant frequency tone extending from time 33 to time 34. Thereafter at time 34 a start symbol 51 is initiated following leader tone 50 and extends to a time 35. Once again, the particular tone combination utilized in start symbol 51 is a matter of design choice within the host audio communication code environment. By way of example, in signal 30, start symbol 51 includes a lower frequency tone 52 followed by a higher frequency tone 53 after which a lower frequency tone 54 and a higher frequency tone 55 are presented. In the preferred fabrication of the present invention, to minimize possibilities of errors and to enhance the accuracy of the system, it has been found preferable to employ a combination of tones within start symbol 51 which is unique and which is clearly distinguishable from the data symbols within the audio communication code system.

Following leader tone 50 and start symbol 51, a first data symbol 60 begins at time 35 and extends to time 36. The particular form of data symbol 60 is selected within the code format to represent the desired bits of data to be communicated. By way of example, data symbol 60 includes a trio of tones 61, 62, and 63 which are successively higher in frequency from the preceding tone. Similarly, the next data symbol 65 begins at time 36 and extends to time 37. By way of further example, data symbol 65 includes tones 66, 67 and 68. It will be noted that the tone combinations of data symbols 60 and 65 differ. This difference in tone combinations comprises the data encoding to be utilized in the present invention system. At time 37 and extending to time 38, data symbol 70 having tones 71, 72 and 73 is presented within signal 30. Thereafter, extending from time 38 to time 39, a data symbol 75 includes tones 76, 77 and 78.

Because the number of data symbols in a given audio communication code signal fabricated in accordance with the present invention is substantial and may be varied, FIG. 2 indicates an indeterminate time extending between time 39 and time 40. In the example of signal 30, it will be understood that in a practical audio communication code system of the type to which the present invention pertains, that this indefinite period of time corresponds to a plurality of data symbols which, in the example of FIG. 2, would each include three frequency tones. From time 40 to time 41, a final data symbol 80 is shown which includes frequency tones 81, 82 and 83.

It will be apparent to those skilled in the art that the use of data symbols having three frequency tones each is a matter of design choice for a given desired information flow rate and capability. Accordingly, it will be understood that data symbols may be utilized in accordance with the present invention having different numbers of frequency tones without departing from the spirit and scope of the present invention. For example, data symbols having two frequency tones rather that three will be easier to detect but result in a lower data rate within the system. Conversely, data symbols having an increased number of frequency tones such as 4, 5, 6 and so on provide increasingly greater data flow rates at the expense of increasing difficulty of detection and decoding. However, it will be understood that the three frequency tone combinations for the data symbols of the illustrative adaptive audio communication code signal shown in FIG. 2 is provided by way of illustration and not limitation.

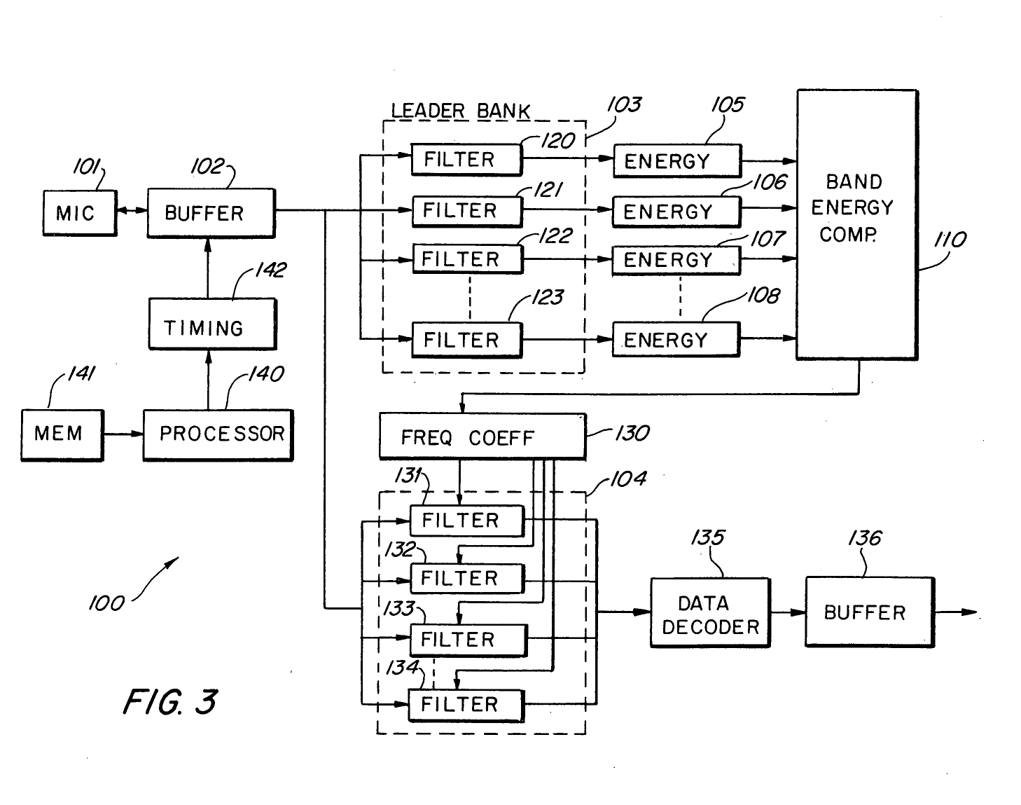

FIG. 3 sets forth an illustrative block diagram of the frequency compensating or adaptive elements within the present invention adaptive audio communication code. The adaptive portion of the present invention audio communication code shown in FIG. 3 and generally referenced by numeral 100 provides detection of frequency errors occurring within the entire audio communication code system including encoding, transmitting, receiving and decoding as well as adaptive accommodation of frequency errors to enable the system to maintain reliable and accurate decoding and recovery of the data being communicated.

It will be noted that the presentation of system 100 in FIG. 3 is provided for information purposes and is illustrative of the basic system operation. In the preferred fabrication of the present invention, the entire adaptive code system is resident within the host computer (personal computer 10 seen in FIG. 1). Accordingly, the processes and elements set forth in FIG. 3 are illustrative of software implementation of the present invention adaptive audio communication code. Notwithstanding this preference for implementing the present invention system in a software environment, it will be recognized that a firm wear or dedicated hardware implementation or a combination thereof may be utilized in carrying forward the present invention adaptive audio communication code without departing from the spirit and scope of the present invention.

More specifically, system 100 includes a microphone 101 fabricated in accordance with conventional fabrication techniques. The acousto-electric conversion of microphone 101 provides digital electronic data which is stored within an input data buffer 102. Buffer 102 is controlled by a timing circuit and clock 142 which in turn is operated by a processor 140. Processor 140 comprises the processor unit of the host personal computer for system 100 and thus includes a cooperating memory 141. Within memory 141, a stored instruction set of program is resident which, together with, operating software for processor 140 facilitates the implementation of the present invention system. Thus, in accordance with an important advantage of the present invention adaptive audio communication code, the computing power and available memory of the personal computer is employed with little or no computing power or memory being required in the sending unit (audio transmitter 20 seen in FIG. 1).

With buffer 102 operating in response to timing system 142, data received by microphone 101 is successively stored within buffer 102 and thereafter is transferred to a leader bank 103. Leader bank 103 comprises a plurality of software filters 120, 121, 122 and an indeterminate number to a final software filter 123. In accordance with the conventional fabrication of software filters, the frequency responses of each of filters 120 through 123 is determined by a set of frequency coefficients. Of importance with respect to the present invention, each of filters 120 through 123 defines a frequency passband response which is maximized or centered at a slightly different frequency. In the preferred fabrication of the present invention, the frequency band responses of the filters within leader bank 103 are selected to define frequencies which are close to but above and below the nominal frequency of the leader portion of the present invention adaptive audio communication code.

Each of the filters within leader bank 103 is coupled to an energy band output measurement unit. More specifically, filter 120 is coupled to an energy band measurement unit 105 while filters 121 and 122 are coupled to measurement units 106 and 107 respectively and filter 123 is coupled to an energy unit 108. The output information of each of energy band measurement units 105 through 108 which forms a number indicative of the energy within the passband of its associated filter, is applied to a band energy comparator 110. Band energy comparator 110 provides a computation which compares the energy outputs from each of the energy band measurements and determines the frequency band having the greatest energy communicated therein. This corresponds to the actual leader tone frequency of the audio communication code signal following transmission, recovery and decoding thereof In response to the determination of frequency band maximum, comparator 110 is coupled to a frequency coefficient 130. Once again, because this is in its preferred form, a software implementation, frequency coefficient unit 130 comprises a portion of the system software which establishes the frequency coefficient for a second plurality of software filters 130 through 134 residing in a data bank 104. Data bank 104 is also coupled to the output of buffer 102 and thus, in response to timing unit 142 receives a succession of coded information beginning with the start symbol and commencing with the series of data symbols. The individual frequency passband responses of the filters within data bank 104 are offset by the coefficient adjustment made by unit 130 in response to the determination of received leader tone frequency. Thus, in accordance with an important aspect of the present invention, the adaptive quality of the present invention adaptive audio communication code is facilitated in response to the frequency error or shift which has occurred in the received and decoded leader tone. This use of the leader tone is the primary element in determining the adjustment of frequency coefficient necessary for use in the decoding of the data symbols in a manner adapting to or compensating for frequency inaccuracies and errors in the system. As a result, filters 131 through 134 of data bank 104 operate with frequency coefficient that are now “centered” upon the actual frequencies of the various tones present within the symbols being detected. Without this adaptive compensation, the system would operate with passband frequencies for each filter within the data bank which assume a center frequency or frequencies not actually existing in the system. The result would be substantial error in the recovered data.

The output of data bank 104 is coupled to the remainder of the present invention adaptive. audio communication code system indicated as data decode 135. Thereafter, the decoded data is transferred to an output buffer 136 which in turn provides a source of decoded data utilized in the remainder of the system.

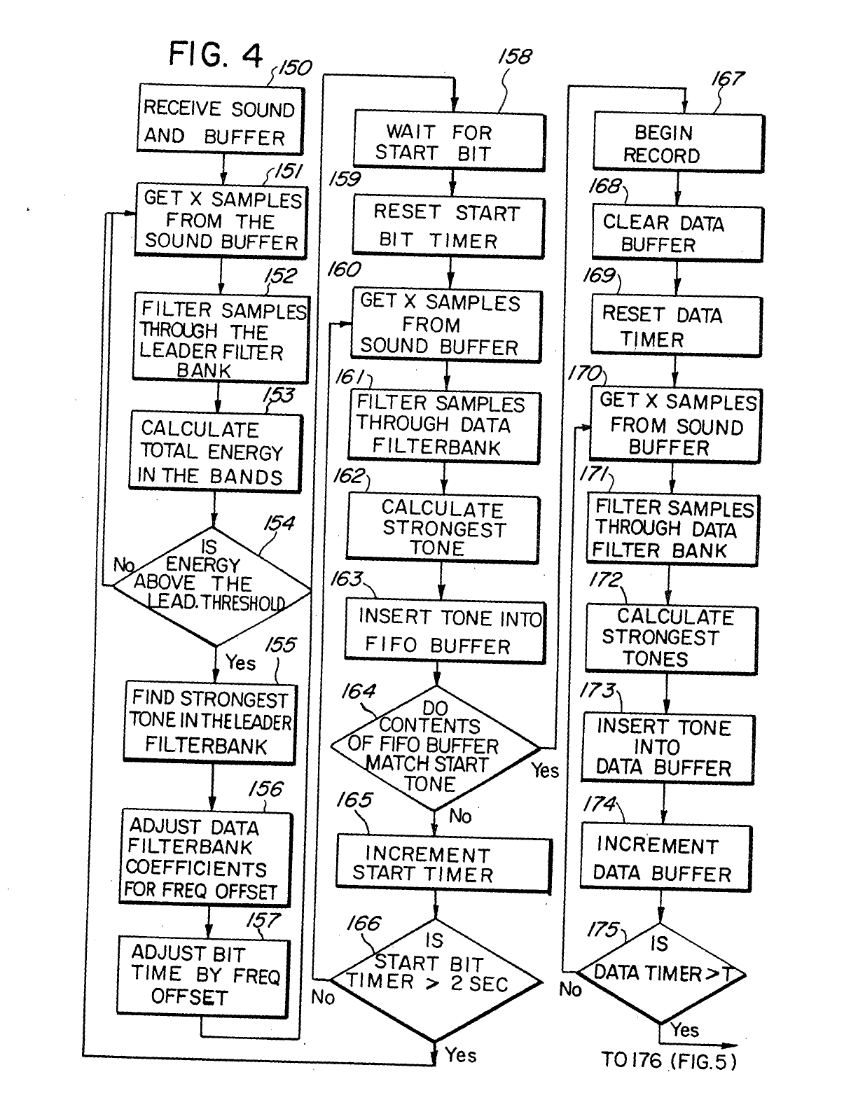

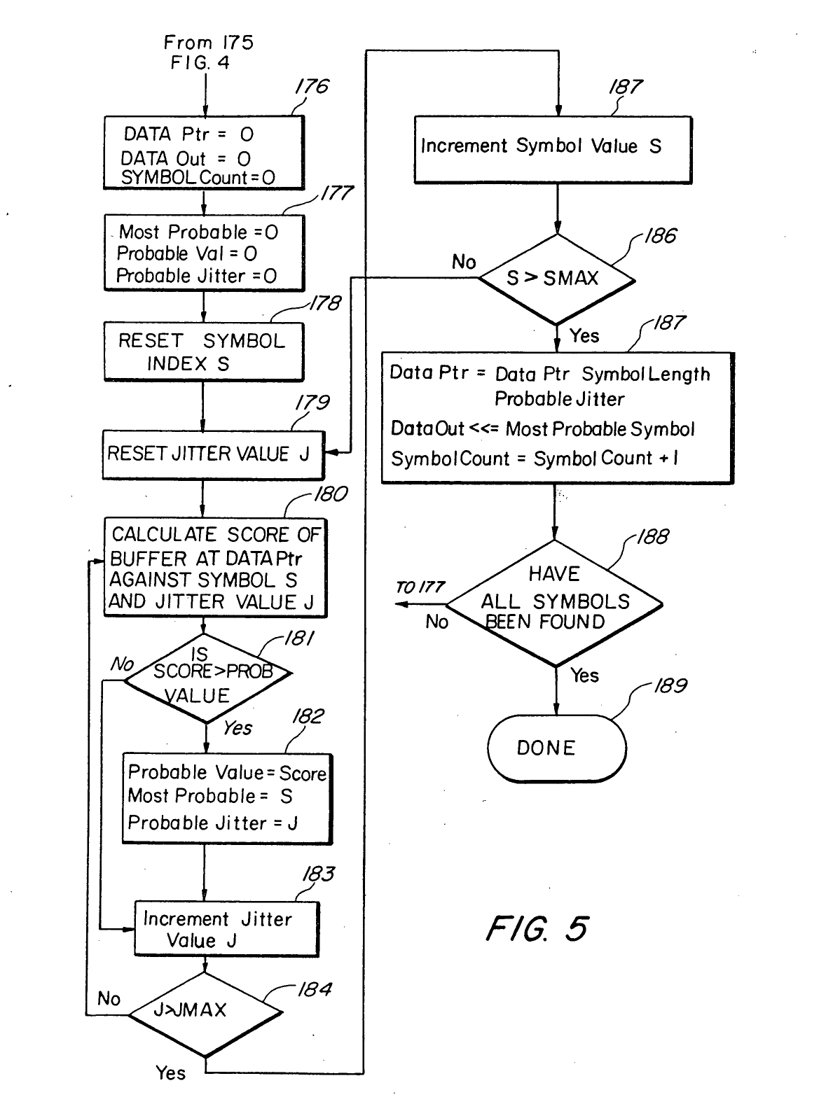

FIGS. 4 and 5 taken together set forth operational flow diagrams of the present invention adaptive audio communication code. For the most part, the operation set forth in FIGS. 4 and 5 represents the operation of the receiving and decoding apparatus of the present invention system. It will be understood that the operation of the audio transmitter (transmitter 20 seen in FIG. 1) is carried forward in accordance with conventional fabrication techniques to provide the sequence of tones such as those shown in FIG. 2 to produce the audio communication code signal which is received by the host system. Accordingly, in FIGS. 4 and 5, it will be assumed initially that an audio communication code signal encoded in the manner set forth in signal 30 of FIG. 2 has been received by the host system within a personal computer in the manner shown in FIG. 1.

More specifically with reference to FIG. 4, system operation commences at a step 150 in which the encoded audio communication is received and stored within an input data buffer. Thereafter at step 151, a predetermined number of samples are transferred from the sound buffer to the leader bank filter. At step 153, the calculation of total energy in the combined filter bands of the leader filter bank is carried forward. Thereafter at step 154, a determination is made as to whether the total energy exceeds the minimum threshold determined for the valid leader tone. In the event the calculated energy does not exceed the minimum leader tone threshold, the system returns to step 151 and the next group of samples is transferred from the sound buffer to the leader filter bank and the process is repeated.

If however at step 154, a determination is made that sufficient energy above the leader threshold is present, the system moves to step 155 in which the energy in each filter band within the leader filter bank is examined to find the filter which exhibits the greatest energy in its pass band. Thereafter at step 156, the coefficient of the filters within the data filter bank is adjusted for frequency offset corresponding to the difference between the actual leader tone frequency and the predetermined or ideal leader tone frequency.

At step 157, the bit time of the data filter bank is also adjusted in accordance With the frequency offset. At step 158, the system looks for a start symbol and at step 159, the start bit timer is reset. At step 160, the next group of samples is transferred from the sound buffer to the data filter bank. At step 161, the samples are filtered within the data filter bank and at step 162, the strongest tone is determined. Thereafter at step 163, the strongest tone is transferred to a serial data buffer or “FIFO” buffer.

At step 164, a determination is made as to whether the buffer contents match the tone frequencies of the start tone. If the contents of the buffer do not match the system moves to step 165 incrementing the start timer afterwhich, at step 166, a determination is made as to whether the start bit timer has exceeded its maximum setting which, in the current example, is two seconds. If the start bit timer has not timed out, the system returns to step 160 selecting the next group of samples from the sound buffer afterwhich, the same filtering and tone calculation is made in steps 161 and 162 afterwhich, the tone is inserted into the buffer and again, at step 164, the contents of the buffer are examined for a match to the start tone. This process repeats until either the start bit timer has timed out, in which case in the absence of a match to the start tone, the system returns to step 151 and repeats steps 151 and following.

If a determination is made at step 164 that a match of tones to the start tone has been found, the system now prepares for the data symbols moving to step 167. Thus, it will be apparent that the sequence-of steps carried forward from step 150 through 167 have embodied the process of employing the frequency examination of the leader tone and the use of a frequency offset based on that examination. Further, at this point, the system has adapted or accommodated any deviation of frequency of the leader tone by correspondingly offsetting the frequency coefficient of the filters within the data bank used to filter the start tone and which will be used to filter subsequent data symbol tones. In other words, at step 167, the system is ready to commence data transfer.

At step 167, the system is ready to begin evaluation of data symbols. Initially, at step 168, the data buffer is cleared while at step 169, the data timer is reset. Thereafter at step 170, the next group of samples from the sound buffer are transferred to the filters-within the data filter bank. At step 171, the samples are filtered through the data filter bank. At step 172, the strongest tone is determined. Each time the strongest tone is determined, it is inserted into the data buffer. Next, the data timer is incremented and a determination is made at step 175 as to whether the data timer has timed out. If the data timer has not timed out, the system returns through steps 167 through 174 resulting in the incrementing of the data timer and the insertion of the next strong tone into the data buffer. Once the data timer has timed out, the system moves to step 176 shown in FIG. 5.

In FIG. 5, the system has moved from having accumulated the tones of the data symbols within the data buffer and has moved to a step 176. At step 176, the data pointer and data out are set to zero. Also the symbol count is set to zero. At step 177, the most probable value, and probable jitter are all set to zero. In other words, steps 176 and 177 have initialized the jitter portion of the system. At step 178, the symbol index is reset and, at step 177, the jitter value is reset to the nominal value.

At step 180, the system calculates the score of buffer at the data pointer against the symbol nominal value and the nominal jitter value. At step 181, a determination is made as to whether the calculated score exceeds the probable value. In the event the calculated score does not exceed the probable value, the system moves directly to step 183 and increments the jitter value. If however the calculated score exceeds the probable value, the system moves to step 182 setting the probable value equal to the calculated score. Therein, the most probable value is set to the nominal score value while the probable jitter value is set to the nominal jitter value.

Following step 182, the system increments the jitter value at step 183 afterwhich, at step 184, a determination is made as to whether the jitter exceeds the maximum allowable jitter value. If the incremented jitter does not exceed the maximum jitter value, the system removes to step 180 and again cycles through steps 180, 181, 182 and 183. This process continues until the jitter exceeds the maximum jitter value. Once this condition prevails, the system moves to step 185 incrementing the symbol value. At step 186, a determination is made as to whether the symbol value has exceeded the maximum symbol value. If not, the system returns to step 179 and again cycles through steps 179 through 185. Once the symbol value exceeds the maximum symbol value, the system moves to step 187 in which the data pointer is increased by symbol length and probable jitter. Also at step 187, the data out is set less than or equal to the most probable symbol and the symbol count is incremented by one. Following step 187, the system determines at step 188 whether all symbols have been found. If not, the system returns to step 177 and again cycles through steps 177 through 187 until a determination is made at step 188 that all symbols have been found. Once all symbols have been found, the system moves to completion at step 189.

What has been shown is an adaptive audio communication code and system which facilitates the communication of data via audio tones in a low cost and effective manner. The system employs the resident power within a personal computer to manage the adaptive aspects of the present invention code in a manner which enables the system to tolerate relatively low cost components such as microphones and speakers while maintaining maximum reliability and system performance. The system utilizes a code construction which allows the system to tolerate substantial interference from extraneous audio sources such as ambient noise or the like. The use of leader tone for frequency offset and frequency error compensation provides a reliable adaptive audio communication code which corrects for frequency errors within virtually the entire encoding, transmitting, receiving, and decoding apparatus of the system.

While particular embodiments of the invention have been shown and described, it will be obvious to those skilled in the art that changes and modifications may be made without departing from the invention in its broader aspects. Therefore, the aim in the appended claims is to cover all such changes and modifications as fall within the true spirit and scope of the invention.

That which is claimed is:

1. An audio communication code comprising:
a leader tone having a sound tone at a selected frequency, said leader tone having a first time interval;
a start symbol following said leader tone having a predetermined sequence of sound tones, said start symbol being indicative of a plurality of data symbols to follow;
a plurality of data symbols following said start symbol having a plurality of sound tone sets the frequencies of said sound tones in each sound tone set defining data corresponding to the data in its respective sound tone set,
said leader tone frequency being used to determine a frequency offset of said leader tone from said selected frequency which is ten applied to said start symbol and said data symbols as a frequency correction.

2. The audio communication code set forth in claim 1 wherein said predetermined sequence of sound tones in said start symbol is not used for any data symbol.

3. The audio communication code set forth in claim 2 wherein each of said data symbols define a predetermined interval equal to all other data symbol intervals.

4. The audio communication code set forth in claim 3 wherein said start symbol defines a start symbol interval greater than said data symbol interval.

5. The audio communication code set forth in claim 4 wherein said first time interval of said leader tone exceeds said start symbol interval.

6. The audio communication code set forth in claim 5 wherein said tones used in said leader tone, said start symbol and said data symbols are audible frequency tones.

7. An audio communication code method comprising the steps of:
forming a leader tone having a sound tone at a selected frequency, said leader tone having a first time interval;
forming a start symbol following said leader tone having a predetermined sequence of sound tones, said start symbol being indicative of a plurality of data symbols to follow;
forming a plurality of data symbols following said start symbol having a plurality of sound tone sets the frequencies of said sound tones in each sound tone set defining data corresponding to the data in its respective sound tone set.
said leader tone frequency being used to determine a frequency offset of said leader tone from said selected frequency which is ten applied to said start symbol and said data symbols as a frequency correction;
converting said leader tone, said start symbol and said plurality of data symbols to sound energy;
receiving said sound energy at a receiver and converting it to electrical signal;
detecting the frequency of said leader tone as received and converted;
determining the frequency offset of said detected frequency from said selected frequency;
offsetting said tones of said start symbol and said plurality of data symbols by said frequency offset; and
decoding said data symbols having said frequency offset to recover said data.

8. The audio communication code set forth in claim 7 wherein said predetermined sequence of sound tones in said start symbol is not used for any data symbol.

9. The audio communication code set forth in claim 8 wherein each of said data symbols define a predetermined interval equal to all other data symbol intervals.

10. The audio communication code set forth in claim 9 wherein said start symbol defines a start symbol interval greater than said data symbol interval.

11. The audio communication code set forth in claim 10 wherein said first time interval of said leader tone exceeds said-start symbol interval.

12. The audio communication code set forth in claim 11 wherein said tones used in said leader tone, said-start symbol and said data symbols are audible frequency tones.
